(19) United States
(12) Patent Application Publication
(10) Pub. No.: US 2025/0158343 A1
(43) Pub. Date: May 15, 2025

(54) DEVICE FOR BROADBAND AMPLIFICATION BY TEMPERATURE-CONTROLLED COMPONENTS

(71) Applicants: L'AIR LIQUIDE SOCIÉTÉ ANONYME POUR L'ETUDE ET L'EXPLOITATION DES PROCÉDÉS GEORGES CLAUDE, Paris (FR); ECOLE NATIONALE D’INGÉNIEURS DE BREST (ENIB), Plouzane (FR)

(72) Inventors: Arnaud GARDELEIN, Sassenage (FR); Ammar SHARAIHA, Plouzane (FR); Pascal MOREL, Bohars (FR)

(21) Appl. No.: 18/691,898

(22) PCT Filed: Sep. 15, 2022
(86) PCT No.: PCT/EP2022/075707

§ 371 Date: Oct. 6, 2024

(30) Foreign Application Priority Data
Sep. 17, 2021 (FR) FR2109804

(51) Int. Cl. H01S 3/10; H01S 3/04; H01S 3/23; H03F 3/04

(52) U.S. Cl. CPC H01S 3/10007; H01S 3/04; H01S 3/2308; H03F 3/04

(57) ABSTRACT

Amplifier device (20) configured to amplify an input signal (SE2), the device comprising:
a wavelength or frequency demultiplexer (22) configured to demultiplex the input signal (SE2) into N intermediate signals (SI21, SI22, SI23) with N greater than or equal to 2,
a set of N amplifiers (AMP1, AMP2, AMP3), each amplifier being configured to receive one of the N intermediate signals (SI21, SI22, SI23) and generate an amplified signal (SI21amp, SI22amp, SI23amp),
a wavelength or frequency multiplexer (24) configured to receive and multiplex the N amplified signals (SI21amp, SI22amp, SI23amp) into an output signal (SS2),
   wherein the amplifying device (20) comprises a temperature control device (26) of the set of N amplifiers (AMP1, AMP2, AMP3), the temperature control device (26) configured to control that the temperature of at least one amplifier is different from that of at least one of the other amplifiers.

### SCOPE OF THE INVENTION

An amplification device configured to amplify an input signal.

### STATE OF THE ART

An amplifier is an electronic or optoelectronic system that amplifies an electrical or optical signal. The energy required for amplification is drawn from the power supply of the system. A perfect amplifier does not distort the input signal: its output is an exact replica of the input with increased power.

Amplifiers are used in almost all circuits in electronics and optics: they can raise the voltage of an electrical signal or the power of an optical signal to a level usable by the rest of the system, increase the output current of a sensor to allow transmission without interference, provide sufficient maximum power to power a load such as a radio antenna or an electroacoustic enclosure.

It is known that an amplifier makes it possible to amplify a signal for a certain bandwidth. In the case of an electrical circuit, the bandwidth defines a range of frequencies in which the signal can be amplified. In the case of an optical circuit, the passband defines a range of frequencies or wavelengths in which the signal can be amplified, frequency and wavelength being related by the equation

$$f = \frac{c}{λ} ,$$

with f defining the frequency of the light wave, c defining the velocity and λ defining the wavelength of the light wave.

Each type of amplifier has a specific bandwidth. For example, an Erbium-doped fibre amplifier has a bandwidth between 1530 and 1560 nm, while Raman effect amplifiers or semiconductor optical amplifiers may have a bandwidth of a few tens of nanometres, between 1280 and 1650 nm.

An ideal amplifier is linear over its entire bandwidth. More particularly, the bandwidth of an amplifier is defined by the bandwidth at −3 dB. The −3 dB bandwidth of an amplifier is the range of frequencies where the voltage or power gain of the amplifier is greater than the maximum gain minus three decibels. This corresponds to a division of the power supplied to the load by two. The bandwidth at −3 dB of an amplifier according to one of the types of amplifiers mentioned above corresponds to about 30 to 60 nm.

There is therefore a need to be able to amplify different input signals whose wavelength or frequency ranges may be different without necessarily changing the number of amplifiers. There is a need to have an amplifier allowing amplification over a wide bandwidth, for example a bandwidth greater than 60 nm. More particularly, there is a need for continuous amplification over a wide range of wavelengths or frequencies to increase throughput in optical telecommunications systems.

The aim of the invention is to provide a device to meet these needs.

### BRIEF DESCRIPTION OF THE INVENTION

To this end, the present invention provides an amplification device configured to amplify an input signal, the device comprising:
a wavelength or frequency demultiplexer configured to demultiplex the input signal into N intermediate signals with N greater than or equal to 2,
a set of N amplifiers, each amplifier being configured to receive one of the N intermediate signals and generate an amplified signal,
a wavelength or frequency multiplexer configured to receive and multiplex the N amplified signals into an output signal,
   wherein the amplification device comprises a device for controlling the temperature of all N amplifiers, the temperature control device being configured to control that the temperature of at least one amplifier is different from that of at least one of the other amplifiers.

Advantageously, the temperature of an amplifier has an impact on the frequency or wavelength position of its bandwidth. In this way, if at least one of the amplifiers has a different temperature than at least one of the other amplifiers, the input signal can be amplified over different wavelengths or frequency ranges.

Advantageously, by modifying the temperature of at least one of the N amplifiers, its bandwidth is modified, in particular the centre frequency of the amplifier bandwidth.

Demultiplexing the input signal forms N different intermediate signals. These N different intermediate signals each have a specific and different range of wavelengths or frequencies. Combining the wavelength or frequency ranges of each of the N different intermediate signals reproduces at least part or all of the wavelength or frequency range of the input signal. Each of these intermediate signals can be amplified by a specific amplifier being adapted to the range of wavelengths or frequencies of the intermediate signal to be amplified. All N amplified intermediate signals are multiplexed to form an output signal. The output signal is then amplified with respect to the input signal over a range of wavelengths and frequencies, and in a particular embodiment, the output signal is amplified with respect to the input signal over the entire range of wavelengths or frequencies of the input signal.

Advantageously, the amplification device may also comprise one or more of the following features, considered individually or in any technically possible combination:
at least one cooling device configured to cool the N amplifiers to a cryogenic temperature, for example a temperature greater than or equal to 40 K and less than or equal to 220 K; and/or
the temperature control device being configured such that each of the N amplifiers is at a different temperature; and/or
the temperature control device is configured such that the temperature difference between at least two of the N amplifiers is greater than or equal to 10K; and/or
the temperature control device is configured such that each of the N amplifiers is at a temperature allowing successive overlap of the passbands of the N amplifiers; and/or
the temperature control device comprises a device for regulating the temperature of at least one of the N amplifiers; and/or
the demultiplexer is configured to demultiplex the input signal into N intermediate signals having the bandwidths in wavelengths or frequencies corresponding to the passbands of the N amplifiers; and/or
the temperature control device comprises:
   a bar made of a material having a thermal conductivity greater than or equal to 20 watts per metre kelvin on which the N amplifiers are arranged,
   a cold spot disposed at a first location of the bar, and
   a temperature control device comprising a temperature sensor disposed at a second location of the bar; and/or
all N amplifiers are identical; and/or
the amplifiers are optical amplifiers; and/or
the amplifiers are semiconductor optical amplifiers; and/or
the temperature control device is configured to control that the temperature of each of the N amplifiers is greater than or equal to 40 K and less than or equal to 220 K; and/or
the amplifiers are optoelectronic amplifiers; and/or
amplifiers are electronic amplifiers.

### BRIEF DESCRIPTION OF THE FIGURES

The invention will be better understood in the light of the following description which is given only as an indication and which is not intended to limit said invention, accompanied by the figures below:

FIG. 1 is a graphical representation of bandwidths of two Erbium-doped fibre amplifiers,

FIG. 2 is a schematic representation of an amplification device according to the invention,

FIG. 3 is a graphical representation of bandwidths of an amplifier subjected to different temperatures,

FIG. 4 is a schematic representation of an amplification device comprising a device for regulating the temperature of the amplifiers according to a first embodiment of the invention,

FIG. 5 is a schematic representation of an amplification device comprising a device for regulating the temperature of the amplifiers according to a second embodiment of the invention,

FIG. 6 is a schematic representation of an amplification device comprising a device for controlling the temperature of the amplifiers according to a first embodiment of the invention,

FIG. 7 is a schematic representation of an amplification device comprising a device for regulating the temperature of the amplifiers according to a second embodiment of the invention.

### DETAILED DESCRIPTION OF THE INVENTION

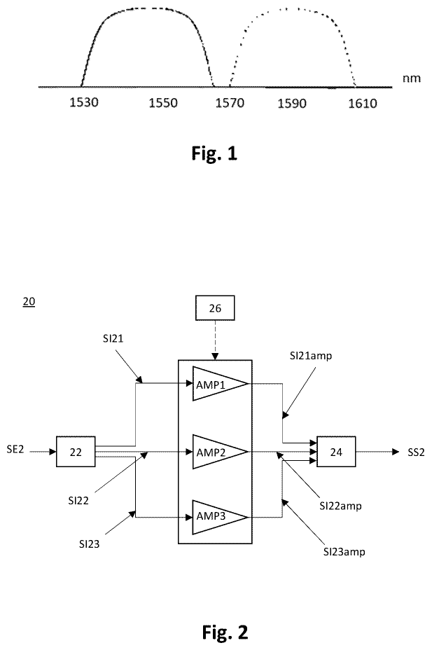

FIG. 1 illustrates the wavelength bandwidths of two amplifiers using Erbium-doped fibre technology. By acting on the dopant, it is possible to shift the passband of the amplifiers as shown in FIG. 1. The first amplifier allows amplification of signals having wavelengths between 1535 and 1560 nm. The second amplifier AMP2 allows amplification of signals having wavelengths between 1575 and 1600 nm.

The amplification device that uses this type of amplifier does not allow an input signal to be amplified over the 1560 to 1575 nm wavelength range.

An amplification device configured to amplify an input signal. To obtain amplification of part or all of the wavelength or frequency range of the input signal, all of the components of that part or all of the wavelength or frequency range of the input signals should be amplified.

The aim of the invention is to be able to widen the range of wavelengths or frequencies over which an input signal can be amplified.

As shown in FIG. 2, a device 20 according to the invention comprising:
a demultiplexer 22,
a set of N amplifiers AMP1, AMP2, AMP3,
a multiplexer 24, and
a device 26 for controlling the temperature of all N amplifiers.

The demultiplexer 22 is a wavelength or frequency demultiplexer configured to demultiplex an input signal SE2 into N intermediate signals SI21, SI22, SI23 with N greater than or equal to 2. In the particular case of FIG. 2, the demultiplexer divides the input signal SE2 into three intermediate signals SI21, SI22, SI23. The three intermediate signals SI21, SI22, SI23 each having a range of different wavelengths or frequencies. The combination of the ranges of wavelengths or frequencies of the different intermediate signals SI21, SI22, SI23 reproduces at least part of the range of wavelengths or frequencies of the input signal SE2.

The bandwidth of an amplifier is usually limited to a few tens of nanometres for an optical amplifier, or between 100 kHz and several tens of GHz for an electronic amplifier, such as an electronic telecommunication amplifier.

Concerning an electronic amplifier, such as an electronic telecommunication amplifier, only the frequency of the signal is usually considered.

With regard to the rest of the description, reference will be made more particularly to an optical amplifier. However, the invention is not limited to such a type of amplifier. For ease of understanding, the description will refer only to the wavelength value ranges of the amplifiers AMP1, AMP2, AMP3. The reasoning is identical, if we consider the frequency pages on which the amplifiers AMP1, AMP2, AMP3 provide amplification. The frequency of the signal to be amplified is inversely proportional to the wavelength of the latter, as specified above.

The input signal SE2, whose wavelength range is greater than a few tens of nanometres, can be divided into N intermediate signals SI21, SI22, SI23 using the demultiplexer 22.

Advantageously, each of the N intermediate signals SI21, SI22, SI23 comprises a range of wavelengths. The wavelength range of the N intermediate signals SI21, SI22, SI23 is of the order of a few tens of nanometres. The range of wavelengths of each of the N intermediate signals SI21, SI22, SI23 is defined so as to overlap in whole or in part with the bandwidth of the amplifier AMP1, AMP2, AMP3 to which the intermediate signal SI21, SI22, SI23 is transmitted. In this way, each of the N intermediate signals SI21, SI22, SI23 transmitted to one of the N amplifiers AMP1, AMP2, AMP3 can be amplified over its entire wavelength range.

In a particular embodiment, the wavelength range of one of the intermediate signals SI21, SI22, SI23 may partially overlap the wavelength range of at least one other of the intermediate signals.

The amplification device comprises a set of N amplifiers AMP1, AMP2, AMP3. Each amplifier receives one of the N intermediate signals SI21, SI22, SI23 and generates an amplified signal SI21amp, SI22amp, SI23amp.

Each of the N amplifiers AMP1, AMP2, AMP3 has a respective bandwidth BP1, BP2, BP3. The bandwidth BP1, BP2, BP3 of each of the N amplifiers is configured so as to be able to amplify the intermediate signal SI21, SI22, SI23 received over at least part of the wavelength range of the intermediate signal received. Preferably, each of the N amplifiers AMP1, AMP2, AMP3 can amplify the intermediate signal SI21, SI22, SI23 received over the entire wavelength range of the intermediate signals received.

The inventors have observed that the temperature of an amplifier influences its bandwidth, in particular the position of this bandwidth. By changing the temperature of an amplifier, the position of the amplifier bandwidth is changed and therefore the terminals of the bandwidth are also changed. In this way, by modifying the frequency or wavelength position of each of the amplifiers of the amplification device, the amplification device can allow amplification of the input signal over a wider range of wavelengths.

Thus, the bandwidths BP1, BP2, BP3 of the N amplifiers AMP1, AMP2, AMP3 are defined by the temperature of each of the N amplifiers.

At least one of the N amplifiers is subjected to a different temperature than the other amplifiers, defining a different bandwidth than the other amplifiers.

In one embodiment, each of the N amplifiers AMP1, AMP2, AMP3 is subjected to a different temperature T1, T2, T3, defining different bandwidths BP1, BP2, BP3.

Each of the N intermediate signals SI21, SI22, SI23 respectively comprises a range of wavelengths P1, P2, P3.

The first intermediate signal SI21, having a range of wavelengths P1, is transmitted to a first amplifier AMP1. The second intermediate signal SI22, having a wavelength range P2, is transmitted to a second amplifier AMP2. The third intermediate signal SI23, having a wavelength range P3, is transmitted to a third amplifier AMP3.

The temperature T1 of the amplifier AMP1 is controlled so that the bandwidth BP1 is configured to encompass the range of wavelengths P1 and to allow the intermediate signal SI21 to be amplified over its entire range of wavelengths. The temperature T2 of the amplifier AMP2 is controlled so that the bandwidth BP2 is configured to encompass the wavelength range P2 and to allow the intermediate signal SI22 to be amplified over its entire wavelength range. The temperature T3 of the amplifier AMP3 is controlled so that the bandwidth BP3 is configured to encompass the wavelength range P3 and to allow the intermediate signal SI23 to be amplified over its entire wavelength range.

In FIG. 2, the first amplifier AMP1 is conditioned at a temperature T1 allowing the amplifier AMP1 to have a bandwidth corresponding to the bandwidth BP1 of the first intermediate signal SI21. The second amplifier AMP2 is conditioned to a temperature T2 allowing the amplifier AMP2 to have a bandwidth corresponding to the bandwidth BP2 of the first intermediate signal SI22. The third amplifier AMP3 is conditioned to a temperature T3 allowing the amplifier AMP3 to have a bandwidth corresponding to the bandwidth BP3 of the first intermediate signal SI23.

Temperatures T1, T2 and T3 are each different from each other.

In a particular embodiment, the temperature difference T1, T2, T3 between at least two of the N amplifiers AMP1, AMP2, AMP3 is greater than or equal to 10K and less than or equal to 50K.

In a particular embodiment, the temperature difference T1, T2, T3 between each pair of amplifiers, sharing a common passband segment, among the N amplifiers AMP1, AMP2, AMP3 is greater than or equal to 10K and less than or equal to 50K.

In a particular embodiment, the temperature difference T1, T2, T3 between each pair of amplifiers, having adjacent passbands, among the N amplifiers AMP1, AMP2, AMP3 is greater than or equal to 10K and less than or equal to 50K.

A first amplifier has a first bandwidth. A second amplifier has a second bandwidth. The upper bound of the first bandwidth is less than the lower bound of the second bandwidth.

An amplifying device comprises a plurality of amplifiers, including the aforementioned first and second amplifiers. The difference is measured between the upper limit of the first passband and the lower limit of the passband of the various other amplifiers of the amplification devices, for amplifiers whose lower limit of the passband is greater than the upper limit of the first passband.

When the deviation between the good upper of the first bandwidth and the lower bound of the second bandwidth is the smallest of the deviations measured, then the first and second bandwidths are considered adjacent.

In an amplification device 20 according to the invention, it is possible that the temperature T1, T2, T3 of at least one of the N amplifiers AMP1, AMP2, AMP3 varies from 1K to 3K with respect to the desired target temperature of the amplifier, as long as the temperature T1, T2, T3 of each of the N amplifiers AMP1, AMP2, AMP3 is different.

The amplification device 20 comprises a wavelength multiplexer 24. The multiplexer receives and multiplexes the N amplified signals SI21amp, SI22amp, SI23amp, amplified respectively by each of the N amplifiers AMP1, AMP2, AMP3.

The multiplexer 24 multiplexes the amplified intermediate signals SI21amp, SI22amp, SI23amp in order to form an output signal SS2.

In a particular embodiment, the output signal SS2 has the same wavelength range as the input signal SE2. The output signal SS2 is a signal corresponding to a signal, of which each of the components of the wavelength range of the input signal has been amplified.

In a particular embodiment, the output signal SS2 has a wavelength range forming one or more parts of the wavelength range of the input signal SE2. Each of the components of the part(s) of the range of the input signal SE2 forming the output signal SS2 being amplified.

According to one embodiment, the amplification device 20 further comprises a device 26 for controlling the temperature of at least one of the N amplifiers AMP1, AMP2, AMP3. The temperature control device 26 is configured to control that the at least one of the N amplifiers AMP1, AMP2, AMP3 has a temperature different from those of the other N amplifiers AMP1, AMP2, AMP3.

According to one embodiment, the amplification device 20 comprises a device 26 for controlling the temperature of each of the N amplifiers AMP1, AMP2, AMP3. The temperature control device 26 is configured to control that each of the N amplifiers AMP1, AMP2, AMP3 is at a different temperature T1, T2, T3.

In one embodiment, a temperature sensor is present at each of the N amplifiers AMP1, AMP2, AMP3 so as to measure their respective temperatures T1, T2, T3. The temperatures T1, T2, T3 measured by the temperature sensors are transmitted to the temperature control device 26. The temperature control device 26 can thus control that at least the measured temperature of two of the N amplifiers AMP1, AMP2, AMP3 is different.

Depending on the extent of the wavelength range of the input signal SE2 and the passbands BP1, BP2, BP3 of the N amplifiers AMP1, AMP2, AMP3, the input signal SE2 is divided into N intermediate signals each having a wavelength range less than or equal to the passband of the amplifier AMP1, AMP2, AMP3 to which the intermediate signal SI21, SI22, SI23 is transmitted.

For example, for a wavelength range of an input signal of 150 nm, at least five amplifiers respectively having a bandwidth of 30 nm are used. The input signal is divided into at least five intermediate signals to be respectively transmitted to one of the at least five amplifiers having a passband adapted to a range of wavelengths of the intermediate signal.

In this way, each of the intermediate signals SI21, SI22, SI23 can be amplified over its entire wavelength range P1, P2, P3. The combination of the wavelength ranges P1, P2, P3 of each of the amplified intermediate signals SI21amp, SI22amp, SI23amp allows amplification of the input signal SE2 over the entire wavelength range of the input signal SE2.

The number N of intermediate signals SI21, SI22, SI23 and amplifiers AMP1, AMP2, AMP3 is conditioned by the width of the wavelength band of the input signal.

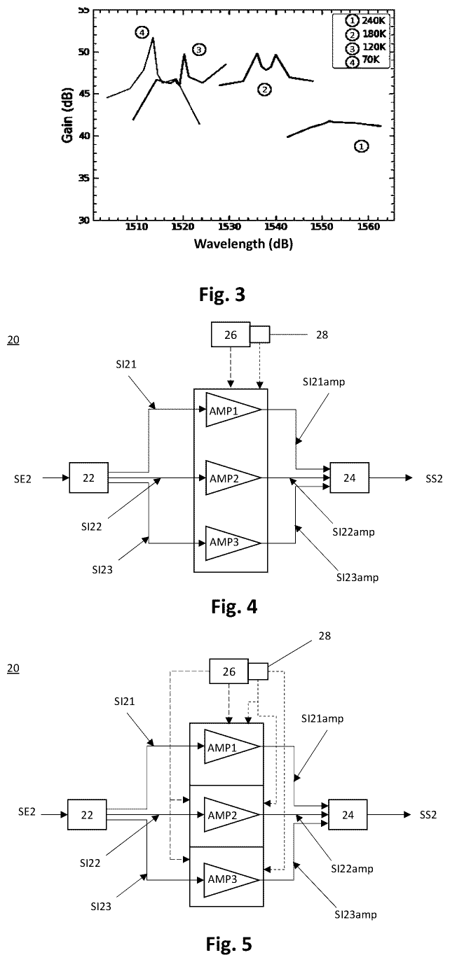

As illustrated in FIG. 3, it has been observed that the temperature of a solid-state optical amplifier has an impact on the wavelength position of its bandwidth. In this way, if each of the amplifiers has a different temperature, the input signal, divided into N intermediate signals, can be amplified over different wavelength ranges.

Thus, two identical amplifiers, at two different temperatures, make it possible to amplify a demultiplexed input signal over two different ranges of wavelengths.

The amplification device is modifiable and makes it possible to guarantee an amplification of an input signal over at least part of its range of wavelengths, even if the lower limit and/or the upper limit of this range varies, by modifying the temperature T1, T2, T3 of the N amplifiers AMP1, AMP2, AMP3.

It may be desirable to prevent part of the input signal SE2 from being amplified, as shown in FIG. 1. To overcome such a problem, regulating the temperature of at least one of the N amplifiers ensures amplification over the wavelength range 1560 to 1575 nm.

Preferably, the temperature control device 26 is configured such that each of the N amplifiers AMP1, AMP2, AMP3 is at a temperature allowing successive overlap of the passbands of the N amplifiers.

Advantageously, an overlap of the passbands of the N amplifiers makes it possible to obtain an amplification on at least part of the wavelengths composing the input signal SE2. This prevents a wavelength range from being amplified, as illustrated in FIG. 1, for the 1560 nm to 1575 nm wavelength range.

By changing the temperature T1, T2, T3 of the N amplifiers AMP1, AMP2, AMP3, the position in the wavelength domain of the bandwidth BP1, BP2, BP3 of each of the N amplifiers is changed. The modification of the position in the wavelength domain of the passband of an amplifier is obtained by modifying the central wavelength of the passband of an amplifier, by acting on the temperature of the amplifier. In this way, by changing the position in the wavelength domain of the passbands of the N amplifiers, the range of wavelengths over which a signal can be amplified is widened, by controlling the temperature of N amplifiers AMP1, AMP2, AMP3.

In a particular embodiment, the temperature control device 26 is configured such that the temperature difference T1, T2, T3 between each of the N amplifiers AMP1, AMP2, AMP3 is greater than or equal to 10K and less than or equal to 50K. Such a temperature difference makes it possible to avoid excessive overlap between two passbands BP1, BP2, BP3 of two of the N amplifiers AMP1, AMP2, AMP3. Advantageously, by reducing the bandwidth overlap of the N amplifiers AMP1, AMP2, AMP3, a smaller number of amplifiers are necessary to amplify an input signal over at least part of its wavelength range.

Thus, preferably, the recovery of the bandwidth between two of the N amplifiers AMP1, AMP2, AMP3 is typically between 1% and 20% of the bandwidth, for example it may be of the order of 5 nm in the case of an optical amplifier having a bandwidth of 50 nm.

FIG. 3 illustrates the wavelength position of the passband of an amplifier, such as a solid-state optical amplifier, at different temperatures. Experiments leading to this invention have shown that for an amplifier, the gain peak shifts as a function of temperature, towards the lower wavelengths.

FIG. 3 also shows that the higher the temperature of the amplifier, the wider the wavelength bandwidth. It is visible that for an amplifier subjected to a temperature of about 70 K, the bandwidth around the gain peak, close to 1510 nm, is very small, on the order of 5 to 10 nm. While under temperature conditions close to 240K, the gain peak is close to 1550 nm, and the bandwidth around the gain peak is larger, and can be in the range of 30-40 nm.

However, if the temperature of an amplifier is too high, the noise generated during amplification is very important. It is thus preferable to keep the amplifiers at temperatures less than or equal to 350K so that the noise generated by the amplification during amplification is acceptable and does not pollute the output signal.

In a particular embodiment, the temperature control device 26 is configured to control that the temperature T1, T2, T3 of each of the N amplifiers AMP1, AMP2, AMP3, cooled by at least one cooling means, is greater than or equal to 40K and less than or equal to 350K, preferably greater than or equal to 120K and less than or equal to 220K, more preferably greater than or equal to 160K and less than or equal to 220K.

Advantageously, when the temperature of a semiconductor optical amplifier is between 40K and 220K, the bandwidth of the amplifiers over which an intermediate signal can be amplified is between 5 nm and 60 nm, and typically between 20 nm and 40 nm for a semiconductor optical amplifier between 120K and 220K.

A cooling device is used to maintain the N amplifiers at temperatures less than or equal to 350K. The cooling device is controlled by a temperature regulating device 28 (see FIGS. 4 to 7).

In a particular embodiment, the cooling device is a passive cooling device, detailed below in the description of FIG. 4.

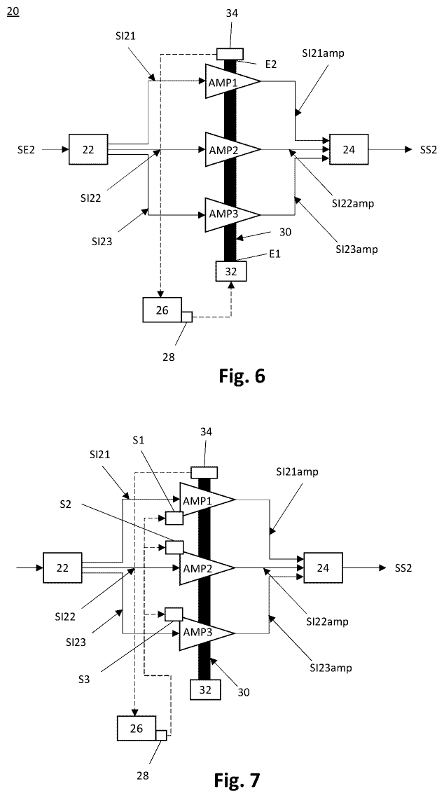

In another particular embodiment, the cooling device is a cryogenic cooling device. An embodiment of the invention comprising such a cooling device is illustrated in FIGS. 6 and 7 and described below.

Temperature regulation of one of the N amplifiers AMP1, AMP2, AMP3 makes it possible to regulate its bandwidth. By changing the temperature of the amplifier whose temperature is regulated, the bandwidth on which the amplifier can amplify a signal is also changed.

Thus, according to one embodiment, the amplification device according to the invention makes it possible to control and/or modify the temperature of at least one of the N amplifiers AMP1, AMP2, AMP3, in order to control and/or modify its bandwidth.

For example, an amplification device according to the invention may comprise an amplifier AMPamb whose temperature is not regulatable and at least two amplifiers AMP1, AMP2 whose temperature is regulatable using the temperature regulation device 28. The AMPamb amplifier has a temperature equivalent to the ambient temperature Tamb of the location where the amplification device is arranged. The first amplifier AMP1 having a controllable temperature is cooled to a temperature T1. The second amplifier AMP2 having a controllable temperature is cooled to a temperature T2.

According to this example, in a first regulation mode, the temperature control device 26 can control only whether the temperature T1 of the first amplifier AMP1 is different from the temperatures T2 and Tamb, in order to provide the amplifier AMP1 with a bandwidth different from the second amplifier AMP2 and the amplifier AMPamb.

If the temperature T1 of the first amplifier AMP1 is equal to one of the temperatures T2 or Tamb, the temperature regulating device 28 can modify the temperature T1 of the first amplifier AMP1, using a cooling device, to be different from the temperatures Tamb and T2, so that each amplifier has a different bandwidth from the amplifiers AMP2 and AMPamb.

According to this example, in a second embodiment, the temperature control device 26 can control the temperature T1 of the first amplifier AMP1 is different from the temperatures T2 and Tamb, and that the temperature T2 of the second amplifier AMP2 is different from the temperatures T1 and Tamb.

If the temperature T1 of the first amplifier AMP1 is equal to one of the temperatures T2 or Tamb, the temperature regulating device 28 can modify the temperature T1 of the first amplifier AMP1, using a cooling device, to be different from the temperatures Tamb and T2, so that each of the amplifiers has a different bandwidth.

Similarly, if the temperature T2 of the second amplifier AMP2 is equal to one of the temperatures T1 or Tamb, the temperature regulating device 28 can modify the temperature T2 of the second amplifier AMP2, using a cooling device, to be different from the temperatures Tamb and T1, so that each of the amplifiers has a different bandwidth.

According to another embodiment, the amplification device according to the invention makes it possible to control and/or modify the temperature of at least one or each of the N amplifiers AMP1, AMP2, AMP3, with a view to controlling and/or modifying their respective bandwidth.

In a particular embodiment, the set of N amplifiers AMP1, AMP2, AMP3 are identical. Advantageously, as illustrated in FIG. 3, different bandwidths BP1, BP2, BP3 can be obtained by the same amplifier according to its temperature.

Amplifiers are considered identical if they have the same nature and the same bandwidth, and more particularly the same bandwidth at the same temperature.

Consequently, an amplification device 20 according to the invention may consist of N identical amplifiers AMP1, AMP2, AMP3 and allow amplification over at least part of the wavelength range of the input signal by regulating the temperature of at least one of the N amplifiers.

In a particular embodiment, the temperature control device comprises a device for regulating the temperature of at least one of the N amplifiers.

FIG. 4 illustrates an electrical or optical diagram reproducing all the characteristics illustrated in FIG. 2. The amplification device 20 according to the invention, illustrated in FIG. 4, illustrates a temperature control device 26 comprising a temperature regulation device 28 for at least one of the N amplifiers AMP1, AMP2, AMP3.

Preferably, to guarantee a temperature difference between two of the N amplifiers AMP1, AMP2, AMP3, it is advantageous to be able to regulate the temperature of at least one of these two amplifiers.

In a preferred embodiment, each of the N amplifiers is temperature regulated independently of the others by the temperature regulating device 28, as illustrated in FIG. 5.

FIG. 6 illustrates a particular embodiment of the temperature control device 26. The temperature control device 26 may include:
a bar 30 made of a material having a high thermal conductivity on which the N amplifiers are arranged (in the case of FIG. 6, three amplifiers AMP1, AMP2 and AMP3 are illustrated),
a cold spot 32 disposed at a first location E1 of the bar 30, and
a temperature regulating device 28 comprising a temperature sensor 34 arranged at a second location E2 of the bar.

Instead of the point E2, located on the bar, the temperature sensor can be located at the cold point 32 or at one of the N amplifiers AMP1, AMP2 and AMP3.

Preferably, the bar 30 has a thermal conductivity greater than or equal to 20 watts per metre kelvin. The temperature at different locations of the bar 30 is different.

In a particular embodiment, the bar 30 is made of copper.

Such an amplification device 20 comprising a bar made of a material having a high thermal conductivity and the presence of a cold spot 32 makes it possible to create a temperature gradient between the first place where the cold source 32 is arranged and one end of the bar 30.

The temperature of the N amplifiers arranged on the bar 30 is conditioned by their location on the bar 30.

The cold spot 32 corresponds to a cooling device configured to cool the bar 30 at a particular location on this bar 30 corresponding to the first location E1.

In a particular embodiment, the cooling device used is a cryogenic cooler.

In this way, the amplifiers arranged closest to the cold spot 32 have a colder temperature than the amplifiers furthest from the straight spot 32.

The cold spot 32 is preferably positioned at one end of the bar 30 to maximise the temperature gradient between a first end and a second end of the bar 30.

With such a temperature gradient, the positioning of the N amplifiers is important to allow said amplifier to be at the desired target temperature.

The positioning of a temperature sensor 34 at a second location E2 of the bar 30 makes it possible to determine the temperature of the bar 30 at this second location E2. Since the bar is made of a conductive material, it can be determined, from the measurement of the temperature sensor 34, at least approximately the temperature at each point of the bar and more particularly at the positions where the N amplifiers AMP1, AMP2 and AMP3 are arranged.

Thus, from the measurement of the temperature at said second location E2 of the bar 30, the temperature control device 26 can determine whether the temperature of the N amplifiers AMP1, AMP2 and AMP3 corresponds to a desired target temperature. If the temperature T1, T2, T3 of at least one of the N amplifiers AMP1, AMP2 and AMP3 is different from the desired target temperature, the temperature control device 26 controls the temperature regulation device 28 to regulate the temperature of the cold spot 32 and consequently the temperature of the N amplifiers.

In such an embodiment, the temperature of each of the N amplifiers AMP1, AMP2, AMP3 can be known using a single temperature sensor 34.

The temperature sensor 34 can be positioned at the cold source, at one of the N amplifiers AMP1, AMP2, AMP3 or at any point on the bar 30.

To use a single temperature sensor, however, it is necessary to know the following parameters:
the temperature at the cold point 32 or a point of the bar 30 or at one of the N amplifiers AMP1, AMP2, AMP3,
the thermal conductivity of the bar 30,
the positioning of the N amplifiers AMP1, AMP2, AMP3 arranged on the bar 30, and
the heat dissipation of each of the N amplifiers AMP1, AMP2, AMP3.

From these parameters, the temperature control device can determine the temperature 26 of the set of N amplifiers AMP1, AMP2, AMP3. In this way, the temperature control device at least two of the N amplifiers is different.

According to one embodiment, the temperature of an amplifier can be derived from the voltage supplying the amplifier. More particularly, in such a particular embodiment, the 4-wire resistance measurement is considered to determine the voltage supplying the amplifiers.

When the temperature is derived from the voltage supplying the amplifier, it is necessary to carry out a calibration making it possible to obtain the relationship between voltage and temperature. As part of the calibration, the current and optical power supplied are controlled.

In the 4-wire resistance measurement method, the 4-wire connection is used. Two of the four wires are used to provide the supply current to the amplifier, and the other two wires are used to measure the voltage across the amplifier.

In another embodiment illustrated in FIG. 7, the temperature control device 26 independently controls the temperature T1, T2, T3 of each of the N amplifiers AMP1, AMP2 and AMP3. If one of the N amplifiers is not at a desired target temperature, the temperature control device independently controls the temperature of that amplifier.

Each of the N amplifiers AMP1, AMP2 and AMP3 is associated with a respective additional heat source S1, S2, S3. Each of the N additional heat sources S1, S2, S3 is configured to individually regulate the temperature of one of the N amplifiers.

In a particular embodiment, each of the N additional thermal sources is Peltier modules.

The embodiment, illustrated in FIG. 7, is similar to the configuration illustrated in FIG. 6, the temperature regulation device 28 is however different. The temperature regulating device 28 no longer regulates the temperature of the cold spot 32 but regulates the temperature of the additional heat sources S1, S2 and S3.

In such an embodiment, to obtain the temperature of each of the N amplifiers AMP1, AMP2, AMP3, it is necessary for a temperature sensor 34 to be positioned at each of the N additional thermal sources S1, S2, S3 or at each of the N amplifiers AMP1, AMP2, AMP3 heated or cooled by one of the N additional thermal sources S1, S2, S3.

The amplification device 20 according to the invention can be used for different types of amplifiers for amplifying an electrical or optical input signal.

In a particular embodiment, the amplification device 20 comprises N amplifiers AMP1, AMP2 and AMP3 which are optical amplifiers.

In a particular embodiment, the amplification device 20 comprises N amplifiers AMP1, AMP2 and AMP3 which are semiconductor optical amplifiers.

In a particular embodiment, the amplification device 20 comprises N amplifiers AMP1, AMP2 and AMP3 which are optoelectronic amplifiers.

In a particular embodiment, the amplification device 20 comprises N amplifiers AMP1, AMP2 and AMP3 which are electronic amplifiers.

Electronic amplifiers comprise passive components having specific properties that vary according to the temperature to which the passive component is subjected. Variations in the properties of these passive components induce a variation in the bandwidth over which a signal can be amplified by the amplifier.

More particularly, electronic amplifiers are composed of materials, such as silicon. The characteristics of amplifiers, such as the bandwidth over which a signal can be amplified, are dependent on the intrinsic physical parameters of the amplifier. These intrinsic parameters are influenced by the temperature to which the amplifier is subjected. For example, temperature has an impact on the mobility of electrons in materials dedicated to their mobility within the amplifier.

The invention has been described above with the aid of embodiments shown in the figures, without limitation of the general inventive concept.

Many other modifications and variations suggest themselves to those skilled in the art, after reflection on the different embodiments illustrated in this application.

These embodiments are given by way of example and are not intended to limit the scope of the invention, which is determined exclusively by the claims below.

In the claims, the word “comprising” does not exclude other elements or steps, and the use of the indefinite article “one” or “one” does not exclude a plurality. The mere fact that different features are listed as mutually dependent claims does not indicate that a combination of these features cannot be advantageously used. Finally, any reference used in the claims shall not be construed as limiting the scope of the invention.

1. Amplifier device (20) configured to amplify an input signal (SE2), the device comprising:
a wavelength or frequency demultiplexer (22) configured to demultiplex the input signal (SE2) into N intermediate signals (SI21, SI22, SI23) with N greater than or equal to 2,
a set of N amplifiers (AMP1, AMP2, AMP3), each amplifier being configured to receive one of the N intermediate signals (SI21, SI22, SI23) and generate an amplified signal (SI21amp, SI22amp, SI23amp),
a wavelength or frequency multiplexer (24) configured to receive and multiplex the N amplified signals (SI21amp, SI22amp, SI23amp) into an output signal (SS2),
wherein the amplifying device (20) comprises a temperature control device (26) of the set of N amplifiers (AMP1, AMP2, AMP3), the temperature control device (26) configured to control that the temperature of at least one amplifier is different from that of at least one of the other amplifiers.

2. The amplifying device of claim 1, wherein the amplifying device (20) comprises at least one cooling device configured to cool the N amplifiers to a cryogenic temperature, for example, a temperature greater than or equal to 40 K and less than or equal to 220 K.

3. Amplifier device according to claim 1, wherein the temperature control device (26) is configured such that each of the N amplifiers (AMP1, AMP2, AMP3) is at a different temperature (T1, T2, T3).

4. Amplification device according to claim 1, wherein the temperature control device is configured such that the temperature difference between at least two of the N amplifiers (AMP1, AMP2, AMP3) is greater than or equal to 10K.

5. Amplification device according to claim 1, wherein the temperature control device (26) is configured such that each of the N amplifiers (AMP1, AMP2, AMP3) is at a temperature (T1, T2, T3) allowing successive overlapping of the passbands (BP1, BP2, BP3) of the N amplifiers (AMP1, AMP2, AMP3).

6. Amplification device according to claim 1, wherein the temperature control device (26) comprises a device (28) for regulating the temperature of at least one of the N amplifiers (AMP1, AMP2, AMP3).

7. Amplification device according to claim 1, wherein the demultiplexer (22) is configured to demultiplex the input signal (SE2) into N intermediate signals (SI21, SI22, SI23) having the wavelength or frequency bandwidths corresponding to the passbands (BP1, BP2, BP3) of the N amplifiers (AMP1, AMP2, AMP3).

8. The amplification device according to claim 1, wherein the temperature control device (26) comprises:
a bar (30) made of a material having a thermal conductivity greater than or equal to 20 watts per meter kelvin on which the N amplifiers are arranged,
a cold spot (32) disposed at a first location on the bar, and
a temperature control device (28) comprising a temperature sensor (34) disposed at a second location of the bar (30).

9. Amplification device according to claim 1, wherein the set of N amplifiers (AMP1, AMP2, AMP3) are identical.

10. Amplification device according to claim 1, wherein the amplifiers (AMP1, AMP2, AMP3) are optical amplifiers.

11. Amplifier device according to claim 10, wherein the amplifiers (AMP1, AMP2, AMP3) are semiconductor optical amplifiers.

12. Amplification device according to claim 1, wherein the temperature control device (26) is configured to control that the temperature (T1, T2, T3) of each of the N amplifiers (AMP1, AMP2, AMP3) is greater than or equal to 40 K and less than or equal to 220 K.

13. Amplification device according to claim 1, wherein the amplifiers (AMP1, AMP2, AMP3) are optoelectronic amplifiers.

14. Amplification device according to claim 1, wherein the amplifiers (AMP1, AMP2, AMP3) are electronic amplifiers.
